(19) United States
(12) Patent Application Publication
(10) Pub. No.: US 2013/0279706 A1
(43) Pub. Date: Oct. 24, 2013

(54) CONTROLLING INDIVIDUAL AUDIO OUTPUT DEVICES BASED ON DETECTED INPUTS

(71) Applicant: Stefan J. Marti, Santa Clara, CA (US)

(72) Inventor: Stefan J. Marti, Santa Clara, CA (US)

(21) Appl. No.: 13/453,786

(22) Filed: Apr. 23, 2012

(51) Int. Cl. H03G 3/20

(52) U.S. Cl. 381/57; 381/107

(57) ABSTRACT

A method is disclosed for rendering audio on a computing device. The method is performed by one or more processors of the computing device. The one or more processors determine at least a position or an orientation of the computing device based on one or more inputs detected by one or more sensors of the computing device. The one or more processors control the output level of individual speakers in a set of two or more speakers based, at least in part, on the at least determined position or orientation of the computing device.

### BACKGROUND OF THE INVENTION

Computing devices have become small in size so that they can be easily carried around and operated by a user. In some instances, users can watch videos or listen to audio, on a mobile computing device. For example, users can operate a tablet device or a smart phone to watch a video using a media player application. Users can also watch videos or listen to audio using speakers of the computing device.

### BRIEF DESCRIPTION OF THE DRAWINGS

The disclosure herein is illustrated by way of example, and not by way of limitation, in the figures of the accompanying drawings and in which like reference numerals refer to similar elements, and in which:

FIG. 1 illustrates an example system for rendering audio on a computing device, under an embodiment;

FIG. 2 illustrates an example method for rendering audio on a computing device, according to an embodiment;

FIGS. 3A-3B illustrate an example computing device for controlling audio output devices, under an embodiment;

FIGS. 4A-4B illustrate automatic controlling of audio output devices on a computing device, under an embodiment; and

FIG. 5 illustrates an example hardware diagram for a system for rendering audio on a computing device, under an embodiment.

### DETAILED DESCRIPTION

Embodiments described herein provide for a computing device that can maintain a consistent and/or uniform audio output field for a user, despite the presence of one or more conditions that would skew or otherwise diminish the audio output for the user. According to embodiments, a computing device is configured to automatically adjust its audio output based on the presence of a specific condition or set of conditions, such as conditions that are defined by the position or orientation of the computing device relative to the user, conditions resulting from surrounding environmental conditions (e.g., ambient noise). As described herein, a computing device can dynamically adjust its audio output to create a consistent audio output field for the user (e.g., as experienced by the user).

As used herein, an audio output is deemed consistent to the perspective of the user if the audio output does not substantially change over a duration of time as a result of the presence of one or more diminishing audio output conditions. An audio output is deemed uniform to the perspective of the user if the audio output does not substantially change in directional influence as experienced by the user (e.g., the user perceives the sound equally in both ears).

In some embodiments, the computing device includes a set of two or more speakers (e.g., left and right side of computing device), which can be spatially displaced from one another on the computing device. Each speaker can include one or more audio output devices (e.g., a speaker can include separate components for bass and treble). Generally, the audio output devices of a given speaker (if a speaker has more than one audio output device) are located together at one location on the computing device. The computing device is configured to independently control an output of each speaker to maintain a consistent and/or uniform audio output field for the user to experience.

In an embodiment, the computing device includes one or more sensors that can detect and provide inputs corresponding to diminishing audio output conditions that would otherwise affect the audio output field experienced by the user. Examples of diminishing audio output conditions include (i) a skewed or tilted orientation of the computing device relative to the user, (ii) a change in proximity of the computing device relative to the user, and/or (iii) environmental conditions. For example, the computing device can automatically control the volume of each speaker in a set of speakers based, at least in part, on the determined position and/or the orientation of the computing device relative to the user. The result is that the audio output, as experienced by the user, remains consistent for the user's perspective despite the occurrence of a condition that would skew or otherwise diminish the audio output field as experienced by the user. Thus, for example, an embodiment provides that the audio output of the computing device to remain substantially consistent and/or uniform before and after the user tilts the device and/or positions it closer or further to his head.

In some embodiments, the computing device can enable or disable one or more speakers in a set of speakers depending on the presence of diminishing audio output conditions. Still further, some embodiments provide for a computing device that can determine the position and/or the orientation of the computing device relative to the position of a user (or the user's head). The position of the computing device can include the distance of the computing device from the user when the device is being operated by the user as well as whether the device is being tilted (e.g., when held by the user or on a docking stand). If the device is moved further away from the user, for example, the computing device can automatically increase the volume level of one speaker over another, or both speakers at the same time, so that the output as experienced by the user remains consistent and/or uniform.

Still further, one or more embodiments provide for a computing device that can adjust an output of one or more speakers independently, to accommodate, for example, (i) a detected skew or non-optimal orientation of the computing device, and/or (ii) a change in the position of the computing device relative to the user. As an example, the computing device can control its speakers separately to account for a tilted or skewed orientation about any of the device's axes, or to account for a change in the orientation of the device about any of its axes (e.g., device orientation changed from a portrait orientation to a landscape orientation, or vice versa).

In one embodiment, the computing device can select one or more rules stored in a database to control individual speakers of the computing device to account for the presence of diminishing audio output conditions. More specifically, the rule selection can be based on conditions, such as (i) a skewed or tilted orientation of the computing device relative to the user, (ii) a change in proximity of the computing device relative to the user, and/or (iii) environmental conditions.

In an embodiment, a volume of individual speakers can be controlled by decreasing a volume of one or more speakers of the set of speakers, and/or increasing the volume of one or more speakers of the set. In some embodiments, the volume of individual speakers can be controlled by decreasing a volume of one or more speakers of the set to be zero decibels (dB) so that no audio is output from one or more of the speakers. By adjusting the different speakers in the set of two or more speakers, the computing device can make the audio field appear substantially uniform to the user despite the user holding the computing device in different positions and/or orientations with respect to the user.

In one embodiment, the computing device can also determine ambient sound conditions around or surrounding the computing device. The ambient sound conditions can be determined based on one or more inputs detected by the one or more sensors of the computing device. For example, the one or more sensors can include one or more microphones to detect sound. Based on the determined ambient sound conditions, the computing device can also control the volume of individual speakers to compensate for the ambient sound conditions.

According to embodiments, the computing device can include sensors in the form of, for example, accelerometer(s) for determining the orientation of the computing device, camera(s), proximity sensors or light sensors for detecting the user, and/or one or more depth sensors to determine a position of the user is relative to the device. The sensors can provide the various inputs so that the processor can determine various conditions relating to the computing device (including ambient light conditions surrounding the device). In some embodiments, the processor can also control the volume of individual speakers based on the location or position of the individual speakers that are provided on the computing device. Based on the determined conditions, the processor can automatically control the audio rendering on the computing device.

One or more embodiments described herein provide that methods, techniques, and actions performed by a computing device are performed programmatically, or as a computer-implemented method. Programmatically, as used herein, means through the use of code or computer-executable instructions. These instructions can be stored in one or more memory resources of the computing device. A programmatically performed step may or may not be automatic.

One or more embodiments described herein can be implemented using programmatic modules or components. A programmatic module or component can include a program, a sub-routine, a portion of a program, or a software component or a hardware component capable of performing one or more stated tasks or functions. As used herein, a module or component can exist on a hardware component independently of other modules or components. Alternatively, a module or component can be a shared element or process of other modules, programs or machines.

Some embodiments described herein can generally require the use of computing devices, including processing and memory resources. For example, one or more embodiments described herein may be implemented, in whole or in part, on computing devices such as desktop computers, cellular or smart phones, personal digital assistants (PDAs), laptop computers, printers, digital picture frames, and tablet devices. Memory, processing, and network resources may all be used in connection with the establishment, use, or performance of any embodiment described herein (including with the performance of any method or with the implementation of any system).

Furthermore, one or more embodiments described herein may be implemented through the use of instructions that are executable by one or more processors. These instructions may be carried on a computer-readable medium. Machines shown or described with figures below provide examples of processing resources and computer-readable mediums on which instructions for implementing embodiments of the invention can be carried and/or executed. In particular, the numerous machines shown with embodiments of the invention include processor(s) and various forms of memory for holding data and instructions. Examples of computer-readable mediums include permanent memory storage devices, such as hard drives on personal computers or servers. Other examples of computer storage mediums include portable storage units, such as CD or DVD units, flash memory (such as carried on smart phones, multifunctional devices or tablets), and magnetic memory. Computers, terminals, network enabled devices (e.g., mobile devices, such as cell phones) are all examples of machines and devices that utilize processors, memory, and instructions stored on computer-readable mediums. Additionally, embodiments may be implemented in the form of computer-programs, or a computer usable carrier medium capable of carrying such a program.

As used herein, the term “substantial” or its variants (e.g., “substantially”) is intended to mean at least 75% of the stated quantity, measurement or expression. The term “majority” is intended to mean more than 50% of such stated quantity, measurement, or expression.

System Description

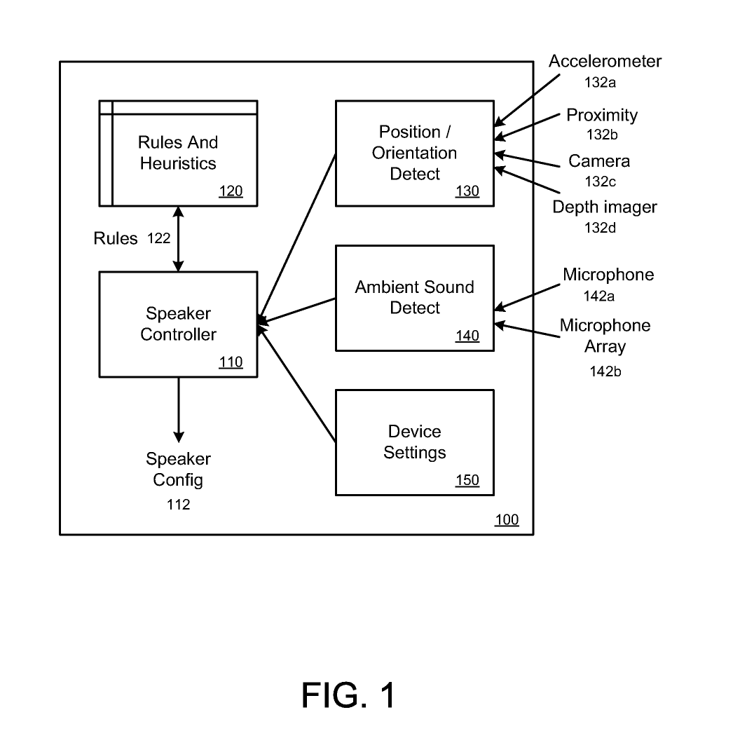

FIG. 1 illustrates an example system for rendering audio on a computing device, under an embodiment. A system such as described with respect to FIG. 1 can be implemented on, for example, a mobile computing device or small-form factor device, or other computing form factors such as tablets, notebooks, desktops computers, and the like. In one embodiment, system 100 can automatically adjust the audio output of the device based on the presence of a specific condition or set of conditions, such as conditions that are defined by the position or orientation of the computing device relative to the user, or conditions resulting from surrounding environmental conditions (e.g., ambient noise). By automatically adjusting the audio output to offset diminishing audio output conditions, a better audio experience can be provided for a user.

According to an embodiment, system 100 includes components such as a speaker controller 110, a rules and heuristics database 120, a position/orientation detect 130, an ambient sound detect 140, and device settings 150. The components of system 100 combine to control individual audio output devices for rendering audio. The system 100 can automatically control the audio output level (e.g., volume level) of individual speakers or audio output devices in real-time, as conditions of the computing device and ambient sound conditions around the device can quickly change while the user operates the device. For example, the device can be constantly moved and repositioned relative to the user while the user is watching a video with audio on her computing device (e.g., the user is walking while watching or shifting positions on a chair). The system 100 can compensate for the diminishing audio output conditions by controlling the output level of individual audio output devices of the device.

System 100 can receive a plurality of different inputs from a number of different sensing mechanisms of the computing device. In one embodiment, the position/orientation detect 130 can receive input(s) from one or more accelerometers 132a, one or more proximity sensors 132b, one or more cameras 132c, one or more depth imagers 132d, or other sensing mechanisms (e.g., a magnetometer). By receiving input from one or more sensors that are provided with the computing device, the position/orientation detect 130 can determine one or more device conditions of the computing device. For example, the position/orientation detect 130 can use input detected by the accelerometer 132a to determine the position and/or the orientation of the computing device (e.g., whether a user is holding the computing device in a landscape orientation, portrait orientation, or a position somewhere in between).

In another example, the position/orientation detect 130 can concurrently determine the distance of the computing device from the user by using input from the proximity sensor(s) 132b, camera(s) 132c and/or depth imager(s) 132d. Such inputs can provide information regarding the location of the user's face (e.g., face tracking or detecting). The position/orientation detect 130 can determine that the device is being held by the user about a foot and a half away from the user's head in a landscape orientation while music is being played back on a media application. The position/orientation detect 130 can use the inputs to detect a change in the device orientation and/or the position (including skew or tilt) relative to the user.

In some embodiments, the position/orientation detect 130 can use the inputs that are detected by the various sensors to also determine whether the device is docked on a docking device (e.g., if the device is stationary) or being held by the user. For example, in some cases, a user may hold a computing device, such as a tablet device, while sitting down on a sofa, and operate the device to use one or more applications (e.g., write an e-mail using an email application, browse a website using a browser application, watch a video with audio or listen to music using a media application). The position/orientation detect 130 can determine that the user is holding and operating the device. The position/orientation detect 130 can also determine that the device is being moved or tilted so that one side of the device is closer to the user than the opposing side of the device (e.g., the device is tilted in one or more directions).

According to an embodiment, the position/orientation detect 130 can use a combination of the inputs from the sensors to also determine, for example, an amount of tilt, skew or angular displacement as between the user (or portion of user) and the device. For example, the position/orientation detect 130 can process input from the camera 132c and/or the depth imager 132d to determine that the user is looking in a downward angle towards the device, so that the device is not being held vertically (e.g., not being held perpendicularly with respect to the ground). By using input from the camera 132c as well as the accelerometer 132a, the position/orientation detect 130 can determine that the user is viewing the display in a downward angle, and that the device is also being held in a tilted position with the display surface facing in a partially upward direction. By using a comprehensive view of the conditions in which the user is operating the computing device, the system 100 can automatically configure 112 one or more audio output devices to create a consistent and uniform audio field from the perspective of the user. Similarly, the system 100 can automatically alter the output level of individual audio output device when there is a change in device position or orientation.

Based on the device conditions and changes in the conditions (e.g., position, tilt, or orientation of the device, or distance the device is being held from the user), the speaker controller 110 can automatically control and configure 112 one or more audio output devices of the computing device. For example, there can be times where the user is not holding the computing device in an ideal position for listening to audio from two or more speakers (e.g., the user is holding the device at a tilt so that one speaker outputting sound is closer to the user than another speaker outputting sound). In such cases, the output level from the speaker that is closer to the user will sound louder than the speaker that is even a little bit further away from the user. System 100 can correct the variances in the audio field by automatically controlling and configuring 112 the output levels of individual speakers of the computing device to create a substantially consistent audio field for the user (e.g., increase the volume level of the speaker that is further from the user slightly depending on how much the device is being tilted).

System 100 also includes the ambient sound detect 140 to detect environmental conditions, such as ambient sound conditions, surrounding the computing device. In one embodiment, the ambient sound detect 140 can receive one or more inputs from one or more microphones 142a or from a microphone array 142b. The microphones 142a or microphone array 142b can detect sound input from noises surrounding the computing device (e.g., voices of people talking nearby, sirens or alarms in the distance, construction noises, etc.) and provide the input to the ambient sound detect 140. Using the inputs, the ambient sound detect 140 can determine the intensity of the ambient noise as well as the location and direction in which the sound is coming from relative to the device.

According to an embodiment, system 100 also includes device settings 150 that can include various parameters, such as speaker properties, physical positions of the speakers on the device, device configurations, etc., for rendering audio. The user can change or configure the parameters manually (e.g., by accessing a settings functionality or application of the computing device or by manually adjusting audio output levels of media in an application or the overall output level of the computing device). The speaker controller 110 can use the device settings 150 in conjunction with the determined conditions and changes in conditions (e.g., position and/or orientation of the device, ambient sound conditions) to automatically control audio output levels of individual audio output devices.

The determined conditions and combination of conditions (as well as the device settings 150, e.g., fixed device settings) can provide a comprehensive view of the manner in which the user is operating the computing device. In some embodiments, based on the conditions that are determined by the components, the speaker controller 110 can access the rules and heuristics database 120 to select one or more rules and/or heuristics 122 (e.g., look up a rule) to use in order to control individual audio output devices of the computing device. One or more rules can be used in combination with each other so that the speaker controller 110 can provide a more consistent audio field from the perspective of the user. When one or more conditions change, other rules are selected from the database 120 corresponding to the changed conditions.

For example, according to an embodiment, the rules and heuristics database 120 can include a rule to increase the output level (e.g., decibel level) of one or more individual audio output devices if the user moves further away from the device while she is listening to audio. Similarly, if the user moves the device closer to her, one rule may be to decrease the output level of one or more speakers so that the perceived sound pressure level (e.g., audio output level or volume) appears to remain consistent from the perspective of the user.

In another example, the rules and heuristics database 120 can also include a rule to increase or decrease the output level of one speaker (or audio output devices of the speaker) as opposed to another speaker depending on the orientation and position of the computing device. In some embodiments, the rules and heuristics database 120 can include a rule to offset the ambient noise conditions around the device by increasing the output level of one or more audio output devices in the direction in which the dominant ambient noise is coming from or increasing the overall output level of the audio output devices as a whole. Such rules 122 can be used in combination with each other by the speaker controller 110 to configure and control 112 individual output devices.

The rules and heuristics database 120 can also include one or more heuristics that the speaker controller 110 dynamically learns when it makes various adjustments to the individual speakers. Depending on different scenarios and conditions that exist while the user is listening to audio, the speaker controller 110 can adjust the rules or store additional heuristics in the rules and heuristics database 120. In one embodiment, the user can indicate via a user input (e.g., the user can confirm or reject automatically altered changes) whether or not the changes made to one or more output devices is preferred or not. After a number of indications rejecting a change, for example, the speaker controller 110 can determine heuristics that better suit the particular user's preference (e.g., do not increase the output levels of a speaker or speakers due to ambient noise conditions that do not seem to bother the user). The heuristics can include adjusted rules that are stored in the rules and heuristics database 120 so that the speaker controller 110 can look up the rule or heuristic when a similar scenario (e.g., based on the determined conditions) arises. The rules and heuristics database 120 can be stored remotely or locally in a memory resource of the computing device.

Based on the determined conditions (via the inputs detected from the sensors), the speaker controller 110 can select one or more rules/heuristics from the rules and heuristics database 120. The speaker controller 110 can control individual output devices based on the selected rule(s). As such, the speaker controller 110 can after the audio rendering to compensate or correct variances that exist due to the determined conditions in which the user is viewing or operating the device (e.g., due to tilt or skew). Because the sensors (e.g., accelerometer 132a, microphone 142a) are continually or periodically detecting inputs corresponding to the device and corresponding to the environment, the system 100 can automatically configure 112 individual output devices and provide a consistent audio experience for the user in real-time.

Methodology

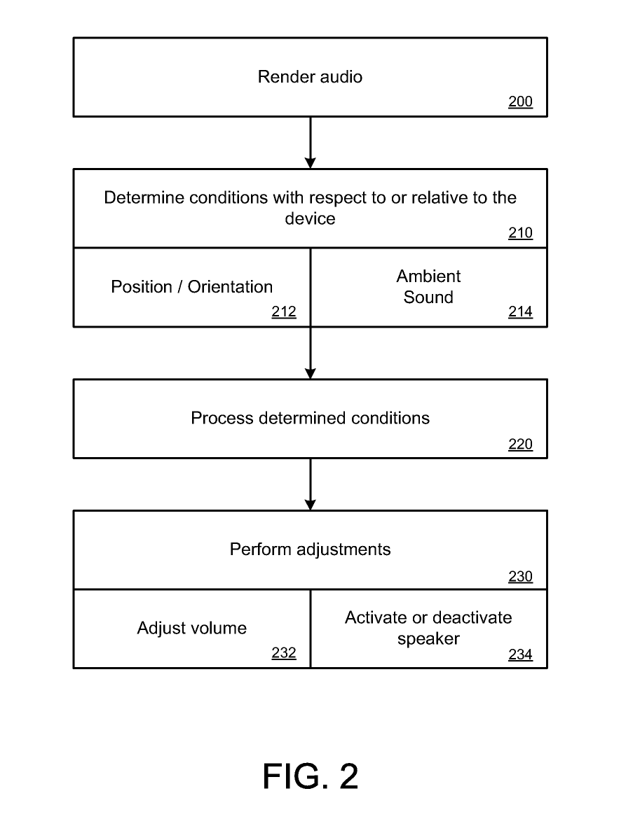

A method such as described by an embodiment of FIG. 2 can be implemented using, for example, components described with an embodiment of FIG. 1. Accordingly, references made to elements of FIG. 1 are for purposes of illustrating a suitable element or component for performing a step or sub-step being described. FIG. 2 illustrates an example method for rendering audio on a computing device, according to an embodiment.

In some embodiments, audio is rendered via one or more audio output devices of the computing device (step 200). A user who is operating the computing device can watch videos with audio, or listen to music or voice recordings (e.g., voicemails). Audio can be rendered from execution of one or more applications on the computing device. Applications or functionalities can include a home page or starting screen, an application launcher page, messaging applications (e.g., SMS messaging application, e-mail application, IM application), a phone application, game applications, calendar application, document application, web browser application, clock application, camera application, media viewing application (e.g., for videos, images, audio), social media applications, financial applications, and device settings. For example, the computing device can be a tablet device or smart phone in which a plurality of different applications can be operated on. The user can open a media application to watch a video (e.g., a video streaming from a website or a video stored in a memory of the device) or to listen to a song (e.g., an mp3 file) so that the audio is rendered on a pair of speakers.

While the user is operating the computing device, e.g., using an application to listen to audio, one or more processors of the device determines one or more conditions corresponding to the manner in which the computing device is being operated and/or ambient sound conditions around the computing device (step 210). The various conditions can be determined dynamically based on one or more inputs that are detected and provided by one or more sensors of the computing device. The one or more sensors can include one or more accelerometers, proximity sensors, cameras, depth imagers, magnetometers, light sensors, or other sensors.

According to an embodiment, the sensors be positioned on different parts, faces, or sides of the computing device to better detect the user relative to the device and/or the ambient noise or sound sources. For example, a depth sensor and a first camera can be on the front face of the device (e.g., on the same face as the display surface of the display device) to be able to better determine how far the user's head is (and ears are) from the computing device as well as the angle in which the user is holding the device (e.g., how much tilt and in what direction). In one example, microphone(s) and/or a microphone array can be provided on multiple sides or faces of the device to better gauge the environmental conditions (e.g., ambient sound conditions) around the computing device.

Based on the different inputs provided by the sensors, the processor can determine the position and/or orientation of the device, such as how far it is from the user, the amount the device is being tilted and in what direction the device is being tilted relative to the user, and the direction the device is facing (North or South) (sub-step 212). The processor can also determine ambient noise or sound conditions (sub-step 214) based on the different inputs detected by the one or more sensors. Ambient sound conditions can include the intensities (e.g., the decibel level of sound around the device, not being produced by the audio output devices of the device) and the direction in which the ambient sound source(s) is coming from with respect to the device. The various conditions are also determined in conjunction with one or more device parameters or settings for individual audio output devices.

The processor of the computing device processes the determined conditions in order to determine how to adjust or control the individual output devices of the computing device (e.g., what adjustments should be made to individual speakers for rendering audio) (step 220). In some embodiments, the determined conditions are continually processed as the sensors detect changes (e.g., periodically) in the manner in which the user operates the device (e.g., the user moves from one location to another, or changes the tilt or orientation of the device). The determined conditions can cause variances in the way the user hears the audio rendered by the audio output devices (from the perspective of the user). Based on the detected conditions, one or more rules and/or heuristics can be selected from the rules and heuristics database. The one or more rules can be used in combination with each other to determine how to adjust or control the individual output devices in order to compensate, correct and/or normalize the audio field from the perspective of the user.

In one embodiment, based on the determined conditions and depending on the one or more rules selected, the speaker controller can control and configure the output levels of individual speakers in a set of speakers of the computing device (step 230). For example, the computing device can have two speakers and the user is listening to music by using a media application. However, the user is holding the device at an angle so that the left speaker (from the perspective of the user) is closer to the user than the right speaker. The computing device can control the individual speakers in the two-speaker set so that the volume of the audio being outputted from the right speaker is increased relative to the left speaker. If the user changes the positioning and tilt of the device, the computing device can adjust the output levels of one or more speakers accordingly. In some embodiments, the speaker controller can control the audio rendering by adjusting various properties, such as the bass or treble.

According to an embodiment, the computing device can adjust the output levels of individual speakers in a set of speakers based on the determined conditions and selected rules (sub-step 232). The sound pressure level (e.g., decibel) of an individual speaker can be increased or decreased relative to one or more other speakers. Similarly, the output level of one or more audio output devices (e.g., separate components for bass and treble) can be adjusted. In some cases, all of the speakers in a set can have the volume level increased or decreased. In another embodiment, the computing device can control individual speakers by activating or deactivating one or more speakers in a set of two or more speakers (sub-step 234). For example, a speaker can be deactivated by not allowing sound to be emitted from the speaker (e.g., decrease the volume or decibel level to zero) or activated to render audio.

The volume of individual speakers can be controlled automatically so that the audio field (from the perspective of the user) can be continually adjusted depending on the inputs that are constantly or periodically detected by one or more sensors. The individual speakers can be controlled in real-time to compensate for constantly changing conditions.

### Usage Examples

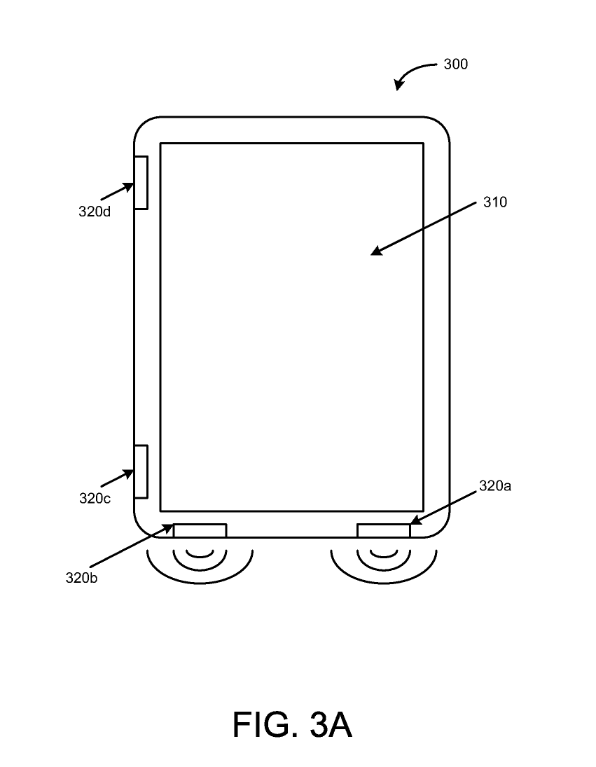

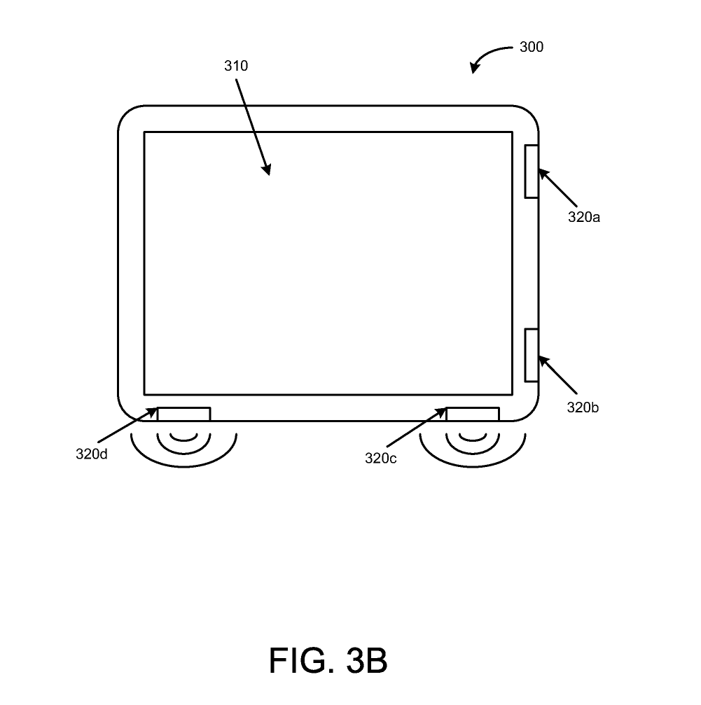

FIGS. 3A-3B illustrate an example computing device for controlling audio output devices, under an embodiment. FIGS. 3A-3B can be performed by using the system described in FIG. 1 and method described in FIG. 2.

In FIG. 3A, the computing device 300 includes a housing with a display screen 310. In some embodiments, the display screen 310 can be a touch-sensitive display screen capable of receiving inputs via user contact and gestures (e.g., via a user's finger or other object). The computing device 300 can include one or more sensors for detecting conditions of the device and conditions around the device while the computing device is being operated by a user. The computing device 300 can include a set of speakers 320a, 320b, 320c, 320d. In other embodiments, the number of speakers provided on the computing device 300 can be more or less than the four shown in this example.

As illustrated in FIG. 3A, the computing device 300 is being operated by a user in a portrait orientation. The user may be operating one or more applications that are executed by a processor of the computing device and interacting with content that is provided on the display screen 310 of the computing device. For example, the user can operate the computing device 300 to make a telephone call using a phone application and use a speakerphone function to hear the audio via the speakers 320a, 320b, 320c, 320d. In another example, the user can listen to music (e.g., that is streaming from a remote source or from an audio file stored on a memory resource of the device) using a media application on the computing device 300. The computing device 300 determines at least a position or an orientation of the computing device 300 (e.g., that the user is holding the device or that the device is about a foot away from the user's head and ears) based on the one or more sensors. In this case, the computing device 300 determines that the orientation is in a portrait orientation.

Based on the determined conditions, the processor of the computing device 300 can cause audio to be outputted or rendered via speakers 320b and 320a. The other two remaining speakers 320c, 320d can be deactivated or their audio output levels be set to zero decibels (dB) so that no sound is emitted from these speakers. In this manner, the computing device 300 can cause sound to be outputted, in the perspective of the user, equally from a left side and a right side of the computing device 300 (e.g., from the perspective of the user, the left and right audio channels can be rendered in a balanced way). Because the left-right channel balance can be automatically adjusted relative to the user, the stereo effect can be optimized for the user based on the orientation and position of the device.

In addition to selecting one or more speakers to output audio and selecting one or more speakers to be disabled (or not output audio), the computing device can also make adjustments to the output levels of the speakers 320a, 320b if diminishing audio output conditions also exist (e.g., the user tilted the device or significant ambient noise conditions are present).

In FIG. 3B, the computing device 300 is being operated by the user in a landscape orientation. While the user is listening to audio or watching a video with audio, upon the user changing the orientation of the computing device 300 from portrait to landscape, the computing device controls the individual speakers 320a, 320b, 320c, 320d to compensate for the changes in the device conditions. As illustrated in FIG. 3B, the one or more processors of the computing device 300 controls each individual speaker so that audio is no longer being rendered using speakers 320a, 320b (e.g., disable or deactivate speakers 320a, 320b by reducing the output level for each to be zero dB), but is instead being rendered using speakers 320d, 320c (e.g., activate speakers 320d, 320c that previously did not render audio). The automatic controlling of individual speakers enables the user to continue to operate and listen to audio with the audio field being consistent to the user despite changes in position and/or orientation of the computing device.

If the audio controlling system (e.g., as described by system 100 of FIG. 1) is inactive or disabled in the computing device 300, the audio would continue to be rendered using the 320a, 320b despite the user changing the orientation of the computing device 300. By automatically controlling individual speakers and output levels of speakers, the computing device 300 can provide a balanced and consistent audio experience from the perspective of the user.

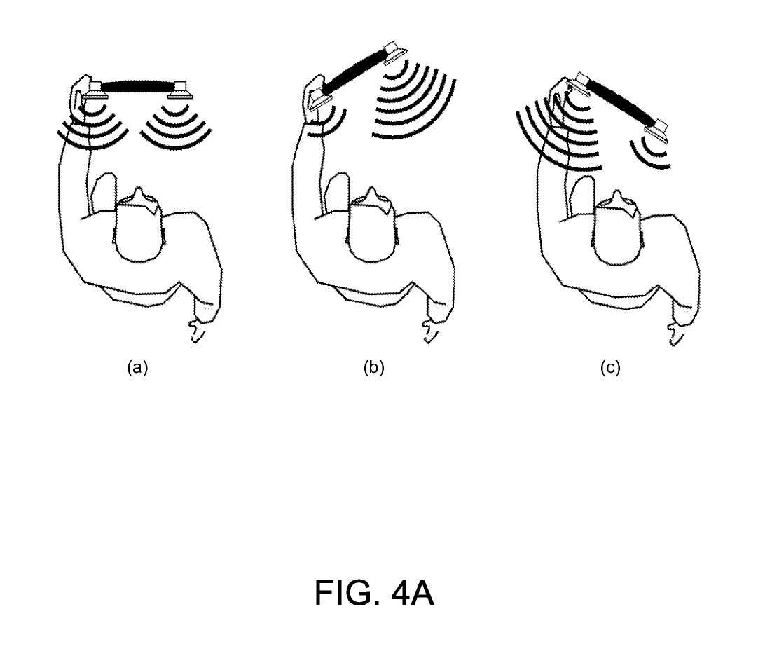

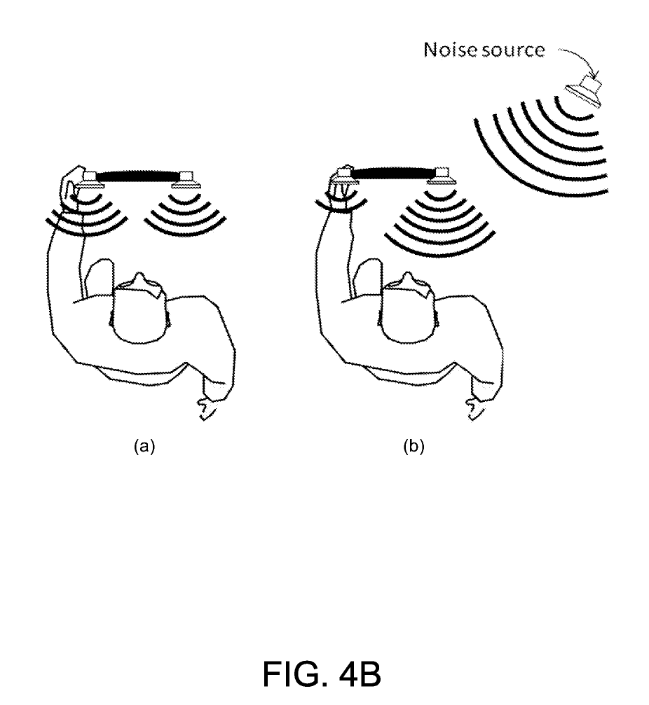

FIGS. 4A-4B illustrate automatic controlling of audio output devices, under an embodiment. The exemplary illustrations of FIGS. 4A-4B represent the way a user is holding and operating a computing device. The automatic controlling of audio output devices as described in FIGS. 4A-4B can be performed by using the system described in FIG. 1, the method described in FIG. 2, and the device described in FIGS. 3A-3B.

FIG. 4A illustrates three scenarios, each illustrating a different way in which the user is holding and viewing content on a computing device. For simplistic illustrative purposes, the computing device described in FIG. 4A is shown with only two speakers. In other embodiments, however, the computing device can include more than two speakers (e.g., four speakers). Also, for simplicity purposes, the audio field (created by the two speakers) is shown as a 2D field. In scenario (a), the user is holding the computing device substantially in front of him so that the left speaker and the right speaker are rendering audio in a balanced manner. For example, the user can set the output level to be a certain amount (e.g., a certain decibel level) as he is watching a video with audio. The computing device can determine where the user's head is relative to the device using inputs from one or more sensors (e.g., use face tracking methods using cameras). Upon determining that the device is being held directly in front of the user, the speakers can be controlled so that the audio is rendered in a balanced manner.

In another example, in scenario (a), if the user is holding the computing device directly in front of him, but moves the device closer or further away from him, the computing device can detect the position of the device relative to the user and control the individual speakers respectively. By determining its position relative to the user, the computing device can process the determined conditions and select one or more rules for adjusting or controlling the audio output levels of individual speakers. For example, if the user moves the device further away from him, the computing device can automatically increase the output level of each speaker (assuming the device is still held directly in front of the user) to compensate for the device being further away. Similarly, if the user moves the device closer to him, the computing device can decrease the output level of each speaker.

When the user rotates or tilts the device from the position shown in scenario (a) to the position shown in scenario (b), the computing device determines its conditions with respect to the user (e.g., dynamically determines the conditions in real-time based on inputs detected by the sensors) and controls the individual speakers to adapt to the determined conditions. By controlling one or more speakers, the stereo effect can be optimized relative to the user. For example, in scenario (b), the device has been moved so that the right side of the device (in a 2D illustration) is further away from the user than the left side of the device. The right speaker is controlled to increase the output level so that the audio field appears consistent from the perspective of the user. For example, when the user is operating the computing device to play a game with music and sound, the user can move the computing device as a means for controlling the game. Because the computing device can control the output level of individual speakers in the set of speakers, despite the user moving the device into different positions, the audio can be rendered to appear substantially balanced and consistent to the user.

Similarly, in scenario (c), the user has moved the device so that it is tilted towards the left (e.g., the front face of the device is facing partially to the left of the user). The left speaker can be controlled to increase the audio output level so that the audio field appears consistent from the perspective of the user.

Note that FIG. 4A is an example of a particular operation of the computing device. Different positions and orientations of the device relative to the user can be possible. For example, although the device is shown in scenarios (b) and (c) to be tilted to the right and left, respectively, the device can be moved or tilted in other directions (and in multiple directions, such as up and down and anywhere in between, e.g., six degrees of freedom). The computing device can also include more than two speakers so that one or more of the speakers can be adjusted depending on the position and/or orientation of the computing device. For example, if the computing device has four speakers, with each speaker being positioned close to a corner of the device, the output level of one or more of the individual speakers can be increased while one or more of the other speakers can be decreased to provide a consistent audio field from the user's perspective.

FIG. 4B illustrates a scenario (a) in which the user is operating the device without significant ambient noise/sound conditions, and a scenario (b) in which the user is operating the device with ambient sound conditions detected by the device. For simplistic illustrative purposes, the computing device described in FIG. 4B is shown with only two speakers. In other embodiments, however, the computing device can include more than two speakers (e.g., four speakers). Also, for simplicity purposes, the audio field (created by the two speakers) is shown as a 2D field.

In scenario (a), the user is holding the computing device substantially in front of him so that the left speaker and the right speaker are rendering audio in a balanced manner. In scenario (a), the computing device has not determined any significant ambient sound conditions that are interfering with the audio being rendered by the computing device (e.g., scenario (a) depicts an undisturbed sound field). In scenario (b), however, an ambient noise or sound source exists and is positioned in front and to the right of the user. The computing device localizes the directional ambient noise using one or more sensors (e.g., a microphone or microphone array) and determines the intensity (e.g., decibel level) of the noise source.

Based on the determined ambient noise conditions, the computing device automatically increases the sound level of the right speaker (because the noise source is coming from the right side of the device and the user and the right speaker is closest to the noise) to compensate for the ambient noise from the noise source (e.g., mask the noise source). By using inputs detected by the one or more sensors, the computing device can substantially determine the position or location of the noise source as well as the intensity of the noise source to compensate for the ambient noise around the device.

In some embodiments, the computing device can control individual speakers based on the combination of both the determined conditions of the device (position and/or orientation with respect to the user as seen in FIG. 4A) and the determined ambient noise conditions (as seen in FIG. 4B). By controlling individual speakers based on various conditions, the system can accommodate mufti-channel audio while increasing audio quality for the user. The computing device can also take into account the directional properties of the speakers and the physical configuration of the speakers on the computing device to control the individual speakers.

Hardware Diagram

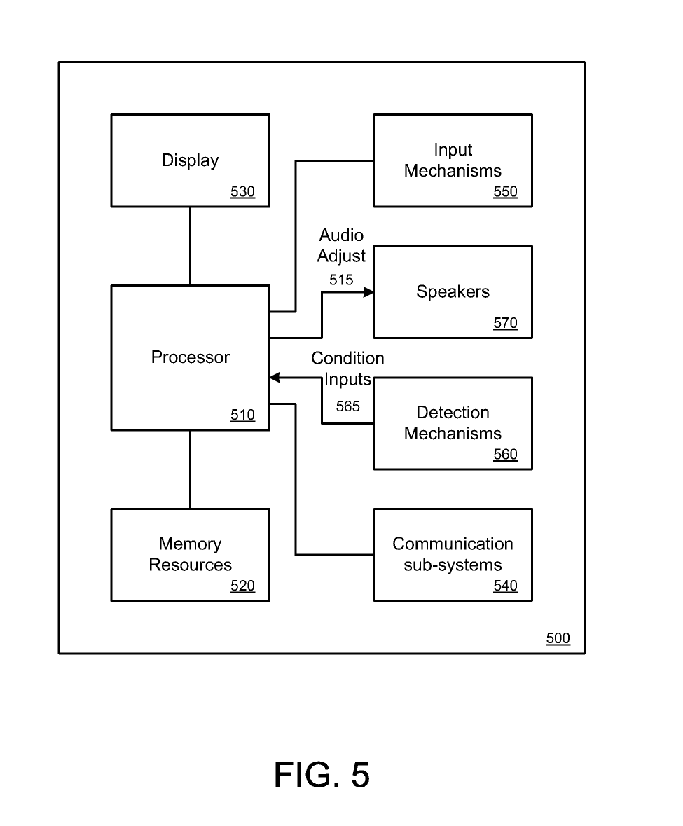

FIG. 5 illustrates an example hardware diagram that illustrates a computer system upon which embodiments described herein may be implemented. For example, in the context of FIG. 1, the system 100 may be implemented using a computer system such as described by FIG. 5. In one embodiment, a computing device 500 may correspond to a mobile computing device, such as a cellular device that is capable of telephony, messaging, and data services. Examples of such devices include smart phones, handsets or tablet devices for cellular carriers. Computing device 500 includes a processor 510, memory resources 520, a display device 530, one or more communication sub-systems 540 (including wireless communication sub-systems), input mechanisms 550, detection mechanisms 560, and one or more audio output devices 570. In one embodiment, at least one of the communication sub-systems 540 sends and receives cellular data over data channels and voice channels.

The processor 510 is configured with software and/or other logic to perform one or more processes, steps and other functions described with embodiments, such as described by FIGS. 1-4B, and elsewhere in the application. Processor 510 is configured, with instructions and data stored in the memory resources 520, to implement the system 100 (as described with FIG. 1). For example, instructions for implementing the speaker controller, the rules and heuristics database, and the detection components can be stored in the memory resources 520 of the computing device 500. The processor 510 can execute instructions for operating the speaker controller 110 and detection components 130, 140 and receive inputs 565 detected and provided by the detection mechanisms 560 (e.g., a microphone array, a camera, an accelerometer, a depth sensor). The processor 510 can control individual output devices in a set of audio output devices 570 based on determined conditions (via condition inputs 565 received from the detection mechanisms 560). The processor 510 can adjust the output level of one or more speakers 515 in response to the determined conditions.

The processor 510 can provide content to the display 530 by executing instructions and/or applications that are stored in the memory resources 520. A user can operate one or more applications that cause the computing device 500 to render audio using one or more output devices 570 (e.g., a media application, a browser application, a gaming application, etc.). In some embodiments, the content can also be presented on another display of a connected device via a wire or wirelessly. For example, the computing device can communicate with one or more other devices using a wireless communication mechanism, e.g., via Bluetooth or Wi-Fi, or by physically connecting the devices together using cables or wires. While FIG. 5 is illustrated for a mobile computing device, one or more embodiments may be implemented on other types of devices, including full-functional computers, such as laptops and desktops (e.g., PC).

### Alternative Embodiments

According to an embodiment, the computing device described in by FIGS. 1-4B can also control an output level of individual speakers in a set of two or more speakers based on multiple users that are operating the device. For example, the computing device can determine the angle and distance of multiple heads of users relative to the device using one or more sensors (such as a camera, or depth sensor). The computing device can adjust the output level of individual speakers based on where each user is so that audio field can be rendered to each user to be substantially consistent from the perspective of each user. In some embodiments, multiple sound fields can be created for each user. This can be done using highly directional speaker devices. For example, using directional speakers, a set of speakers can be used to render audio for one user (e.g., a user who is on the left side of the device) and another set of speakers can be used to render audio for another user (e.g., a user who is on the right side of the device).

In another embodiment, the computing device can control individual speakers of a set of speakers when the user is using the computing device for an audio and/or video conferencing communication. For example, during a video conference call between the user of the computing device and two other users, video and/or images of the first caller and the second caller can be displayed side by side on a display screen of the computing device. Based on the orientation and position of the computing device, as well as the location of the first and second callers on the display screen relative to the user, the computing device can selectively control individual speakers to make it appear as though sound is coming from the direction of the first caller or the second caller when one of them talks during the video conferencing communication. If the first caller on the left side of the screen is talking, one or more speakers on the left side of the device can render audio, whereas if the second caller on the right side of the screen is talking, one or more speakers on the right side of the device can render the audio. The individual speakers can be controlled to allow for better distinction between the multiple participants from the perspective of the user.

Similarly, in another embodiment, during an audio conference call, the computing device can maintain the spatial or stereo panorama of the audio field despite the user changing the position and orientation of the computing device. For example, if there are two or more callers speaking into the same microphone on the other end of the communication, the computing device can control the individual speakers so that the spatial panorama of where the callers' voices are coming from can be substantially maintained.

According to one or more embodiments, the computing device can be used for mufti-channel audio rendering in different types of sound formats (e.g., surround sound 5.1, 7.1, etc.). The number of speakers provided on the computing device can vary (e.g., two, four, eight, or more) depending on some embodiments. For example, eight speakers can be found on a tablet computing device with two speakers on each side of the computing device. Having more speakers provides more controlling of the audio field and more adjustment options for the computing device. In one embodiment, one or more speakers can be found on the front face of the device and/or the rear face of the device. Depending on the orientation and position of the device relative to the user, the computing device can switch from using front speakers to back speakers, or between side speakers (e.g., decrease the output level of one or more speakers of a set of speakers to be zero dB, while causing audio to be rendered on another one or more speakers).

It is contemplated for embodiments described herein to extend to individual elements and concepts described herein, independently of other concepts, ideas or system, as well as for embodiments to include combinations of elements recited anywhere in this application. Although embodiments are described in detail herein with reference to the accompanying drawings, it is to be understood that the invention is not limited to those precise embodiments. As such, many modifications and variations will be apparent to practitioners skilled in this art. Accordingly, it is intended that the scope of the invention be defined by the following claims and their equivalents. Furthermore, it is contemplated that a particular feature described either individually or as part of an embodiment can be combined with other individually described features, or parts of other embodiments, even if the other features and embodiments make no mentioned of the particular feature. Thus, the absence of describing combinations should not preclude the inventor from claiming rights to such combinations.

What is claimed is:

1. A method for rendering audio on a computing device, the method being performed by one or more processors and comprising:
determining at least a position or an orientation of the computing device based on one or more inputs detected by one or more sensors of the computing device; and
controlling an output level of individual speakers in a set of two or more speakers based, at least in part, on the at least determined position or orientation of the computing device.

2. The method of claim 1, wherein determining at least the position or the orientation of the computing device includes determining the position or the orientation of the computing device relative to a user's head.

3. The method of claim 1, wherein controlling the output level of individual speakers includes using one or more rules stored in a database.

4. The method of claim 1, wherein controlling the output level of individual speakers includes at least one of: (i) decreasing an output level of one or more speakers of the set, (ii) decreasing an output level of one or more speakers of the set to zero decibels (dB), or (iii) increasing an output level of one or more speakers of the set.

5. The method of claim 1, further comprising determining ambient sound conditions around the computing device.

6. The method of claim 5, wherein controlling the output level of individual speakers is also based on the determined ambient sound conditions.

7. A computing device comprising:
a set of two or more speakers;
one or more sensors; and
a processor coupled to the set of two or more speakers and the one or more sensors, the processor to:
determine at least a position or an orientation of the computing device based on one or more inputs detected by the one or more sensors of the computing device; and
control an output level of individual speakers in the set of two or more speakers based, at least in part, on the at least determined position or orientation of the computing device.

8. The computing device of claim 7, wherein the one or more sensors includes at least one of: (i) one or more microphones, (ii) one or more accelerometers, (iii) one or more cameras, or (iv) one or more depth sensors.

9. The computing device of claim 7, wherein the processor determines at least the position or the orientation of the computing device by determining the position or the orientation of the computing device relative to a user's head.

10. The computing device of claim 7, wherein the processor controls the output level of individual speakers by using one or more rules stored in a database.

11. The computing device of claim 7, wherein the processor controls the output level of individual speakers by performing at least one of: (i) decreasing an output level of one or more speakers of the set, (ii) decreasing an output level of one or more speakers of the set to zero decibels (dB), or (iii) increasing an output level of one or more speakers of the set.

12. The computing device of claim 7, wherein the processor further determines ambient sound conditions around the computing device based one or more inputs detected by the one or more sensors.

13. The computing device of claim 12, wherein the processor controls the output level of individual speakers in the set of two or more speakers based on the determined ambient sound conditions.

14. The computing device of claim 7, wherein the processor controls the output level of individual speakers in the set of two or more speakers based on positions of the set of two or more speakers.

15. A non-transitory computer readable medium storing instructions that, when executed by a processor, cause the processor to perform steps comprising:
determining at least a position or an orientation of the computing device based on one or more inputs detected by one or more sensors of the computing device; and
controlling an output level of individual speakers in a set of two or more speakers based, at least in part, on the at least determined position or orientation of the computing device.
